(19) United States
(12) Patent Application Publication
(10) Pub. No.: US 2023/0260869 A1
(43) Pub. Date: Aug. 17, 2023

(54) SEMICONDUCTOR DEVICE

(71) Applicant: Mitsubishi Electric Corporation, Tokyo (JP)

(72) Inventors: Yuki MATSUTAKA, Tokyo (JP); Kazuhiro ISHIGUCHI, Tokyo (JP)

(73) Assignee: Mitsubishi Electric Corporation, Tokyo (JP)

(21) Appl. No.: 18/057,721

(22) Filed: Nov. 21, 2022

(30) Foreign Application Priority Data
Feb. 16, 2022 (JP) 2022-22276

(51) Int. Cl. H01L 23/40; H01L 23/10; H01L 23/498

(52) U.S. Cl. CPC H01L 23/4006; H01L 23/10; H01L 23/49838; H01L 2023/4068

(57) ABSTRACT

A semiconductor device includes: a semiconductor element; sealing resin formed into a rectangular shape in a top view to seal the semiconductor element; a first heat radiation plate electrically connected to a first electrode, and protruding from a first side of the sealing resin in a top view; a second heat radiation plate electrically connected to a second electrode, and protruding from a second side facing the first side of the sealing resin in a top view; a first terminal electrically connected to the first electrode, and protruding from a third side intersecting with the first side of the sealing resin in a top view; and a second terminal electrically connected to the second electrode, and protruding from the third side of the sealing resin in a top view, wherein the first heat radiation plate and the second heat radiation plate can be fixed to the heatsink.

### BACKGROUND OF THE INVENTION

### Field of the Invention

The present disclosure relates to a semiconductor device.

### Description of the Background Art

When a bridge circuit is made up using a through hole-type package semiconductor device, a plurality of semiconductor devices need to be connected via a bonding wire, a lead terminal, and a substrate. Thus, parasitic inductance increases and surge voltage is easily generated. A switching speed of a semiconductor element included in the semiconductor device needs to be reduced to suppress the surge voltage. Particularly, when a semiconductor material of the semiconductor element is a wide bandgap semiconductor, the switching speed is higher than a case of using conventional Si as the semiconductor material, thus there is a problem in suppressing the surge voltage.

For example, International Publication No. 2020/255663 discloses a surface-mounted package semiconductor device. The semiconductor device described in International Publication No. 2020/255663 includes sealing resin, a plurality of leads protruding from the sealing resin, and a plurality of semiconductor elements electrically connected to the plurality of leads, and the plurality of semiconductor devices can be connected via a metal plate (corresponding to a heat radiation plate) in the plurality of leads. In the semiconductor device described in International Publication No. 2020/255663, parasitic inductance decreases compared with a case of a through hole-type package semiconductor device, thus occurrence of surge voltage can be suppressed.

### SUMMARY

In the semiconductor device described in International Publication No. 2020/255663, an input lead and an output lead are provided as the metal plates, however, it is not assumed that these leads are fixed to a heatsink. Thus, it is difficult to improve a heat radiation property in the semiconductor device.

An object of the present disclosure is to provide a technique capable of suppressing occurrence of surge voltage and improving a heat radiation property in a semiconductor device.

A semiconductor device according to the present disclosure is a semiconductor device which can be connected to a heatsink. The semiconductor device includes a semiconductor element, sealing resin, a first heat radiation plate, a second heat radiation plate, a first terminal, and a second terminal. The semiconductor element includes a first electrode and a second electrode. The sealing resin is formed into a rectangular shape in a top view to seal the semiconductor element. The first heat radiation plate is electrically connected to the first electrode, and protrudes from a first side of the sealing resin in a top view. The second heat radiation plate is electrically connected to the second electrode, and protrudes from a second side facing the first side of the sealing resin in a top view. The first terminal is electrically connected to the first electrode, and protrudes from a third side intersecting with the first side of the sealing resin in a top view. The second terminal is electrically connected to the second electrode, and protrudes from the third side of the sealing resin in a top view. The first heat radiation plate and the second heat radiation plate can be fixed to the heatsink.

For example, when two semiconductor devices are connected to each other, the first heat radiation plate of one semiconductor device and the second heat radiation plate of the other semiconductor device can be connected to each other, thus parasitic inductance is reduced, and occurrence of the surge voltage can be suppressed.

The first heat radiation plate and the second heat radiation plate are fixed to the heatsink, thus a heat radiation property of the semiconductor device can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view of a semiconductor device according to an embodiment 1.

FIGS. 2A and 2B are a top view and a front view of the semiconductor device according to the embodiment 1.

FIG. 3 is a front view illustrating a state where the plurality of semiconductor devices according to the embodiment 1 are connected to each other and fixed to a heatsink.

FIG. 4 is a perspective view of a semiconductor device according to a modification example of the embodiment 1.

FIGS. 5A and 5B are a top view and a front view of the semiconductor device according to the modification example of the embodiment 1.

FIG. 6 is a perspective view of a semiconductor device according to an embodiment 2.

FIGS. 7A and 7B are a top view and a front view of the semiconductor device according to the embodiment 2.

FIG. 8 is a front view illustrating a state where the plurality of semiconductor devices according to the embodiment 2 are connected to each other and fixed to a heatsink.

FIG. 9 is a perspective view of a semiconductor device according to an embodiment 3.

FIGS. 10A and 10B are a top view and a front view of the semiconductor device according to the embodiment 3.

FIG. 11 is a front view illustrating a state where the plurality of semiconductor devices according to the embodiment 3 are connected to each other and fixed to a heatsink.

FIG. 12 is a perspective view of a semiconductor device according to an embodiment 4.

FIGS. 13A and 13B are a top view and a front view of the semiconductor device according to the embodiment 4.

FIG. 14 is a front view illustrating a state where the plurality of semiconductor devices according to the embodiment 4 are connected to each other and fixed to a heatsink.

FIG. 15 is a perspective view of a semiconductor device according to an embodiment 5.

FIGS. 16A and 16B are a top view and a front view of the semiconductor device according to the embodiment 5.

FIG. 17 is a front view illustrating a state where the plurality of semiconductor devices according to the embodiment 5 are connected to each other and fixed to a heatsink.

### DESCRIPTION OF THE PREFERRED EMBODIMENTS

### Embodiment 1

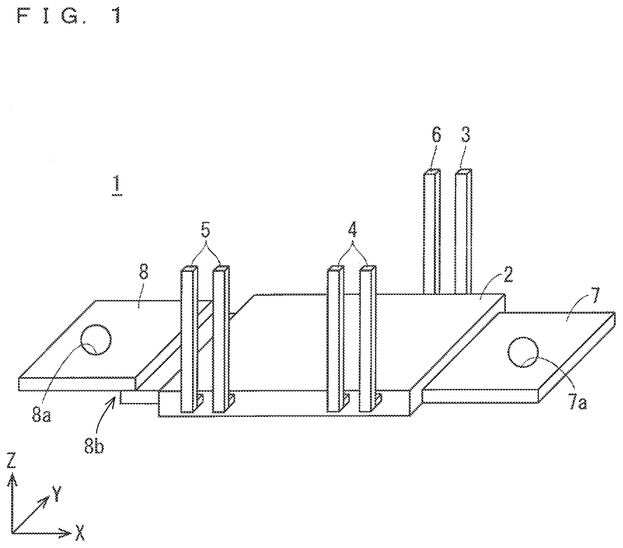

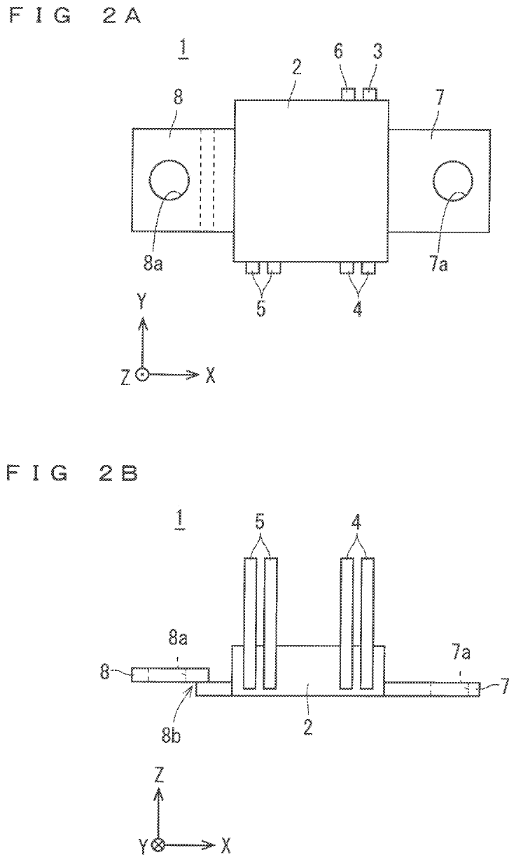

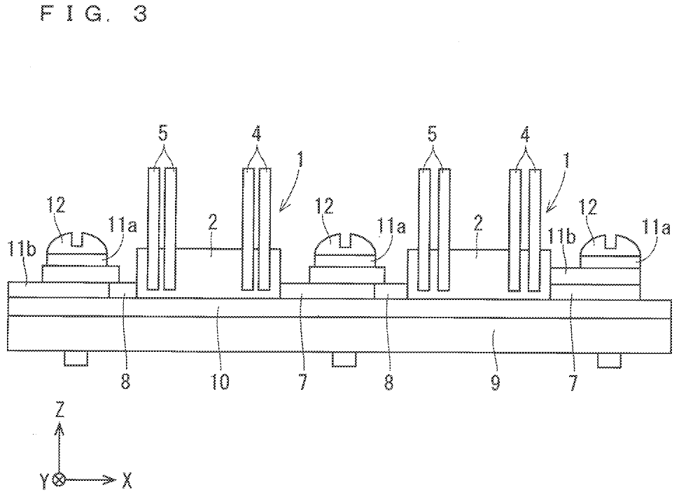

An embodiment 1 is described hereinafter using the drawings. FIG. 1 is a perspective view of a semiconductor device 1 according to the embodiment 1. FIG. 2A is a top view of the semiconductor device 1, and FIG. 2B is a front view of the semiconductor device 1. FIG. 3 is a front view illustrating a state where the plurality of semiconductor devices 1 are connected to each other and fixed to a heatsink 9.

In FIG. 1, an X direction, a Y direction, and a Z direction are perpendicular to each other. An X direction, a Y direction, and a Z direction illustrated in the subsequent drawings are also perpendicular to each other. In the description hereinafter, a direction including the X direction and a −X direction as a direction opposite to the X direction is also referred to as “an X axis direction”. In the description hereinafter, a direction including the Y direction and a −Y direction as a direction opposite to the Y direction is also referred to as “a Y axis direction”. In the description hereinafter, a direction including the Z direction and a −Z direction as a direction opposite to the Z direction is also referred to as “a Z axis direction”.

As illustrated in FIG. 1 and FIGS. 2A and 2B, the semiconductor device 1 is a surface-mounted package semiconductor device, and includes a semiconductor element (not shown), a sealing resin 2, a gate terminal 3, two drain terminals 4 as first terminals, two source terminals 5 as second terminals, a driver source terminal 6, a heat radiation plate 7 as a first heat radiation plate, and a heat radiation plate 8 as a second heat radiation plate.

In the embodiment 1, the semiconductor element is a metal-oxide-semiconductor field effect transistor (MOSFET), and flows current from a source electrode to a drain electrode when a signal is inputted from a gate electrode. The sealing resin 2 is formed into a rectangular shape in a top view to seal the semiconductor element. The sealing resin 2 includes a first side, a second side, a third side, and a fourth side in a top view. Herein, the first side is a side in an X direction in the sealing resin 2, and the second side is a side in a −X direction in the sealing resin 2. The third side is a side in a −Y direction in the sealing resin 2, and the fourth side is a side in a Y direction in the sealing resin 2.

Two drain terminals 4 are electrically connected to the drain electrode of the semiconductor element, and protrude to an upper side (Z direction) from the third side intersecting with the first side of the sealing resin 2 in a top view. Two source terminals are electrically connected to the source electrode of the semiconductor element, and protrude to the upper side (Z direction) from the third side of the sealing resin 2 in a top view. The gate terminal 3 is electrically connected to the gate electrode of the semiconductor element, and protrudes to the upper side (Z direction) from the fourth side facing the third side of the sealing resin 2 in a top view. The driver source terminal 6 is electrically connected to a driver source electrode of the semiconductor element, and protrudes to the upper side (Z direction) from the fourth side of the sealing resin 2 in a top view. Herein, the drain electrode corresponds to the first electrode, and the source electrode corresponds to the second electrode.

As illustrated in FIG. 3, the heat radiation plate 7 and the heat radiation plate 8 are fixed to the heatsink 9 via an insulating sheet 10 to transmit heat generated in the semiconductor element to the heatsink 9. As illustrated in FIG. 1 and FIGS. 2A and 2B, the heat radiation plate 7 is electrically connected to the drain electrode of the semiconductor element, and protrudes in the X direction from the first side of the sealing resin 2 in a top view. The heat radiation plate 8 is electrically connected to the source electrode of the semiconductor element, and protrudes in the −X direction from the second side facing the first side of the sealing resin 2 in a top view. Two drain terminals 4 are provided on a side of the heat radiation plate 7 (X direction) in the third side of the sealing resin 2, and two source terminals 5 are provided on a side of the heat radiation plate 8 (−X direction) in the third side of the sealing resin 2.

The heat radiation plate 7 is formed by a plate-like member made of copper, for example, and does not have a level difference. A tip end portion of the heat radiation plate 7 is provided with a screw hole 7a passing from an upper surface to a lower surface. As illustrated in FIG. 3, a screw 12 is inserted into the screw hole 7a. The screw 12 has a function of fixing the semiconductor device 1 to the heatsink 9 and a function of connecting the plurality of semiconductor devices 1 disposed along the X axis direction. Herein, a base end portion of the heat radiation plate 7 is a portion shifted in the −X direction in relation to the screw hole 7a of the heat radiation plate 7.

As illustrated in FIG. 1 and FIGS. 2A and 2B, the heat radiation plate 8 is formed to have a level difference 8b by bonding end portions of two plate-like members made of copper, for example, overlapped with each other in the Z direction. A tip end portion of the heat radiation plate 8 is provided with a screw hole 8a passing from an upper surface to a lower surface. As illustrated in FIG. 3, a screw 12 is inserted into the screw hole 8a. Herein, a base end portion of the heat radiation plate 8 is a portion shifted in the −X direction in relation to the screw hole 8a of the heat radiation plate 8.

The heat radiation plate 7 and the heat radiation plate 8 protrude from the same height position of the sealing resin 2. The level difference 8b is provided between a lower surface of the tip end portion and a lower surface of the base end portion of the heat radiation plate 8, and a height position of the lower surface of the tip end portion of the heat radiation plate 8 and a height position of the upper surface of the base end portion of the heat radiation plate 7 are the same as each other.

As illustrated in FIG. 3, when two semiconductor devices 1 are fixed to the upper surface (surface in the +Z direction) of the heatsink 9 via the insulating sheet 10, in the semiconductor device 1 on a left side (−X direction), a spacer 11b is disposed on the lower surface (surface in the −Z direction) of the tip end portion of the heat radiation plate 8 to resolve the level difference 8b of the heat radiation plate 8, that is to say, a distance from the tip end portion of the heat radiation plate 8 to the insulating sheet 10, and the spacer 11b is fixed to the heatsink 9 together with the heat radiation plate 8 with the screw 12. A spacer 11a intervenes between the screw 12 and the heatsink 9 to insulate the screw 12 from the heatsink 9.

The lower surface (surface in the −Z direction) of the tip end portion of the heat radiation plate 8 in the semiconductor device 1 on a right side (X direction) is firmly attached to the upper surface (surface in the Z direction) of the base end portion of the heat radiation plate 7 in the semiconductor device 1 on the left side (−X direction). The screw hole 7a of the heat radiation plate 7 and the screw hole 8a of the heat radiation plate 8 are communicated with each other in a state where the heat radiation plate 7 and the heat radiation plate 8 are firmly attached to each other. The heat radiation plate 8 and the heat radiation plate 7 are fixed to the heatsink 9 with the screw 12. The space 11a intervenes between the screw 12 and the heatsink 9 to insulate the screw 12 from the heatsink 9.

In the semiconductor device 1 on the right side (X direction), the spacer 11b is disposed on the upper surface (surface in the Z direction) of the heat radiation plate 7 to conform the height position of the screw 12 used for the heat radiation plate 7 of the semiconductor device 1 to the height position of the other screw 12, and the spacer 11b is fixed together with the heat radiation plate 7 with the screw 12. The space 11a intervenes between the screw 12 and the heatsink 9 to insulate the screw 12 from the heatsink 9. Although not shown in the drawings, each of the lead terminals 3 to 6 are electrically connected to a pattern provided in a substrate on which the semiconductor device 1 is mounted.

As described above, the height position of the lower surface of the tip end portion of the heat radiation plate 7 and the height position of the upper surface of the base end portion of the heat radiation plate 8 are the same as each other, thus two semiconductor devices 1 do not deviate from attachment positions, but the heat radiation plate 8 included in the semiconductor device 1 on the right side (X direction) and the heat radiation plate 7 included in the semiconductor device 1 on the left side (−X direction) can be connected in a closely-attached state.

The state where the height position of the lower surface of the tip end portion of the heat radiation plate 7 and the height position of the upper surface of the base end portion of the heat radiation plate 8 are the same as each other includes not only a case where they are completely the same as each other but also a case where there is a little difference therebetween due to a manufacturing error, for example.

It is sufficient that a level difference is provided in one of the heat radiation plates 7 and 8, and the level difference may be provided in the heat radiation plate 7.

As described above, the semiconductor device 1 according to the embodiment 1 is the semiconductor device 1 which can be connected to the heatsink 9, and includes: the semiconductor element having the drain electrode and the source electrode; the sealing resin 2 formed into the rectangular shape in a top view to seal the semiconductor element; the heat radiation plate 7 electrically connected to the drain electrode and protruding from the first side of the sealing resin 2 in a top view; the heat radiation plate 8 electrically connected to the source electrode and protruding from the second side facing the first side of the sealing resin 2 in a top view; the drain terminal 4 electrically connected to the drain electrode and protruding from the third side intersecting with the first side of the sealing resin 2 in a top view; and the source terminal 5 electrically connected to the source electrode and protruding from the third side of the sealing resin in a top view, and the heat radiation plate 7 and the heat radiation plate 8 can be fixed to the heatsink 9.

Accordingly, when two semiconductor devices 1 are connected to each other, for example, the heat radiation plate 7 of one semiconductor device 1 and the heat radiation plate 8 of the other semiconductor device 1 can be connected to each other, thus parasitic inductance is reduced, and occurrence of the surge voltage can be suppressed.

The heat radiation plate 7 and the heat radiation plate 8 are fixed to the heatsink 9, thus a heat radiation property of the semiconductor device 1 can be improved.

When a bridge circuit, for example, are made up using a plurality of products, symmetry of a circuit pattern between the products or parallel arms can be easily kept, thus current unbalance between the products or parallel arms can be suppressed.

One of the heat radiation plate 7 and the heat radiation plate 8 has the level difference, and the height position of the lower surface of the tip end portion of one heat radiation plate and the height position of the upper surface of the base end portion of the other heat radiation plate are the same as each other, thus the semiconductor devices 1 do not deviate from the attachment positions, but the heat radiation plate 8 included in the semiconductor device 1 on the right side (X direction) and the heat radiation plate 7 included in the semiconductor device 1 on the left side (−X direction) can be connected in the closely-attached state.

The heat radiation plate 7 and the heat radiation plate 8 are provided with the screw holes 7a and 8a, respectively, to be fixed to the heatsink 9, thus the heat radiation plates 7 and 8 can be connected more easily with the screw 12.

### Modification Example of Embodiment 1

A modification example of the embodiment 1 is described next. The semiconductor element may be a transistor other than the MOSFET. Examples of the transistor other than the MOSFET include an insulated gate bipolar transistor (IGBT). The semiconductor element may be a diode. The same applies to the subsequent embodiments.

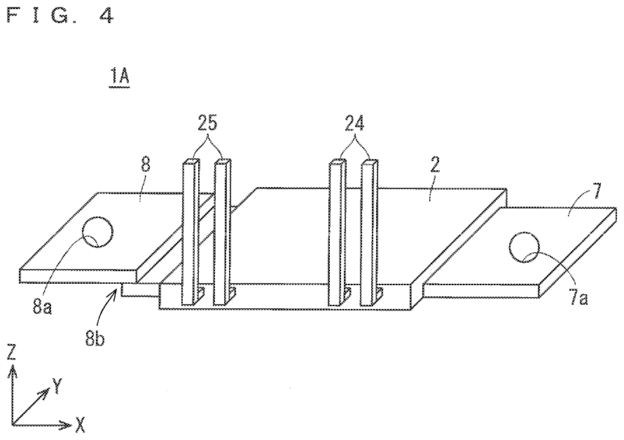

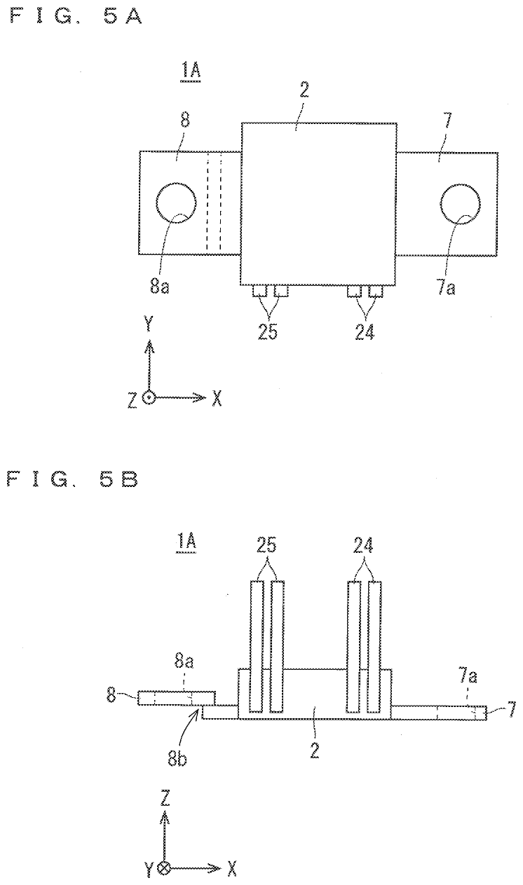

A semiconductor device 1A in a case where the semiconductor element is the diode is described next. FIG. 4 is a perspective view of the semiconductor device 1A according to the modification example of the embodiment 1. FIG. 5A is a top view of the semiconductor device 1A, and FIG. 5B is a front view of the semiconductor device 1A.

As illustrated in FIG. 4 and FIGS. 5A and 5B, the semiconductor device 1A includes the semiconductor element (not shown), the sealing resin 2, two cathode terminals 24 as the first terminals, two anode terminals 25 as the second terminals, the heat radiation plate 7 as the first heat radiation plate, and the heat radiation plate 8 as the second heat radiation plate.

Two cathode terminals 24 are electrically connected to a cathode electrode of the semiconductor element, and protrude to the upper side (Z direction) from the third side intersecting with the first side of the sealing resin 2 in a top view. Two anode terminals 25 are electrically connected to an anode electrode of the semiconductor element, and protrude to the upper side (Z direction) from the third side of the sealing resin 2 in a top view.

The heat radiation plate 7 is electrically connected to the cathode electrode of the semiconductor element, and protrudes in the X direction from the first side of the sealing resin 2 in a top view. The heat radiation plate 8 is electrically connected to the anode electrode of the semiconductor element, and protrudes to the −X direction from the second side facing the first side of the sealing resin 2 in a top view. The other configuration of the semiconductor device 1A is the same as that of the semiconductor device 1, thus the description is omitted.

### Embodiment 2

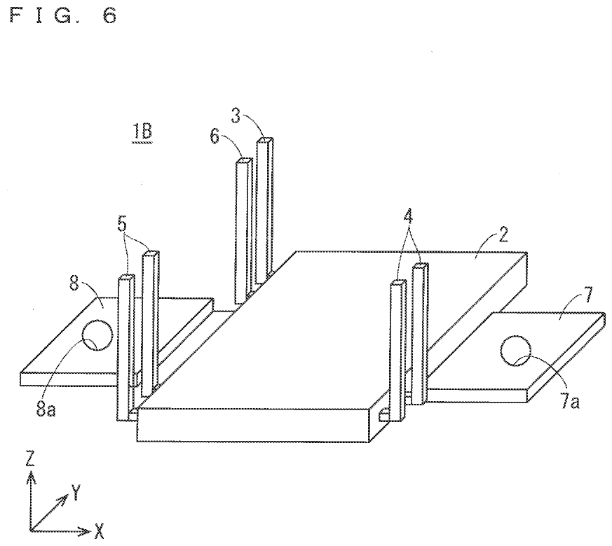

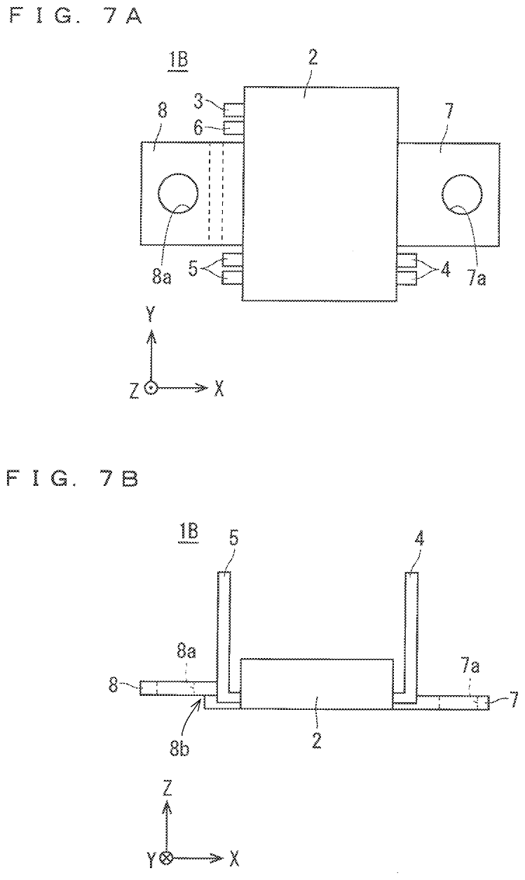

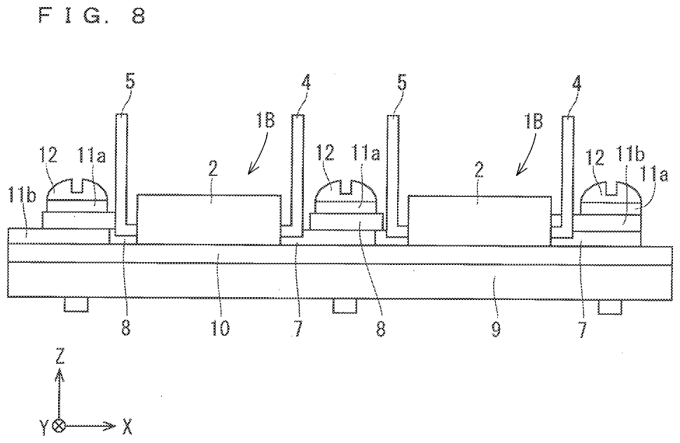

A semiconductor device 1B according to an embodiment 2 is described next. FIG. 6 is a perspective view of the semiconductor device 1B according to the embodiment 2. FIG. 7A is a top view of the semiconductor device 1B, and FIG. 7B is a front view of the semiconductor device 1B. FIG. 8 is a front view illustrating a state where the plurality of semiconductor devices 1B are connected to each other and fixed to the heatsink 9. In the description in the embodiment 2, the same reference numerals are assigned to the same constituent elements as those described in the embodiment 1, and the description thereof will be omitted.

As illustrated in FIG. 6 to FIG. 8, the semiconductor device 1B according to the embodiment 2 is a surface-mounted package semiconductor device, and in the embodiment 2, a position of each terminal is different from that in the embodiment 1.

Two drain terminals 4 as the first terminals protrude to the upper side (Z direction) from the first side of the sealing resin 2 in a top view. Two drain terminals 4 are provided in positions shifted to a front side (−Y direction) in relation to the heat radiation plate 7.

Two source terminals 5 as the second terminals protrude to the upper side (Z direction) from the second side of the sealing resin 2 in a top view. Two source terminals 5 are provided in positions shifted to the front side (−Y direction) in relation to the heat radiation plate 7.

The gate terminal 3 and the driver source terminal 6 protrude to the upper side (Z direction) from the second side of the sealing resin 2 in a top view. The gate terminal 3 and the driver source terminal 6 are provided in positions shifted to a back side (Y direction) in relation to the heat radiation plate 7.

As described above, the semiconductor device 1B according to the embodiment 2 is the semiconductor device 1B which can be connected to the heatsink 9, and includes: the semiconductor element having the drain electrode and the source electrode; the sealing resin 2 formed into the rectangular shape in a top view to seal the semiconductor element; the heat radiation plate 7 electrically connected to the drain electrode and protruding from the first side of the sealing resin 2 in a top view; the heat radiation plate 8 electrically connected to the source electrode and protruding from the second side facing the first side of the sealing resin 2 in a top view; the drain terminal 4 electrically connected to the drain electrode and protruding from the first side of the sealing resin 2 in a top view; and the source terminal 5 electrically connected to the source electrode and protruding from the second side of the sealing resin 2 in a top view, and the heat radiation plate 7 and the heat radiation plate 8 can be fixed to the heatsink 9.

Accordingly, occurrence of surge voltage can be suppressed, and a heat radiation property can be improved in the semiconductor device 1B in the manner similar to the case of the embodiment 1. Furthermore, a creeping distance from the drain terminal 4 to the source terminal 5 can be increase compared with the case of the embodiment 1, thus high withstand voltage of the semiconductor device 1B can be achieved.

### Embodiment 3

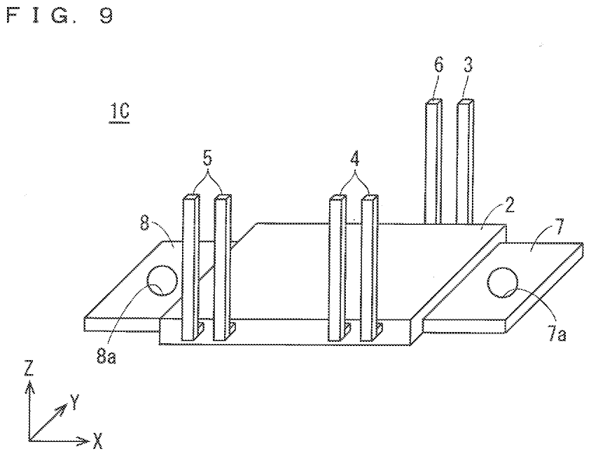

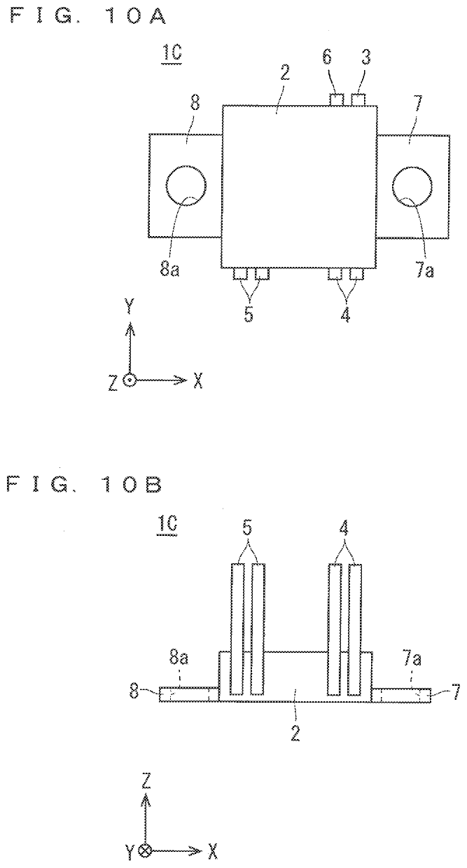

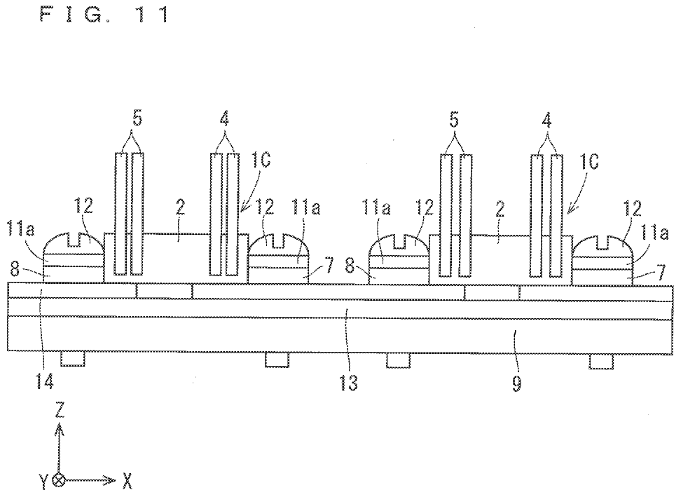

A semiconductor device 1C according to an embodiment 3 is described next. FIG. 9 is a perspective view of the semiconductor device 1C according to the embodiment 3. FIG. 10A is a top view of the semiconductor device 1C, and FIG. 101B is a front view of the semiconductor device 1C. FIG. 11 is a front view illustrating a state where the plurality of semiconductor devices 1C according to the embodiment 3 are connected to each other and fixed to a heatsink 9. In the description in the embodiment 3, the same reference numerals are assigned to the same constituent elements as those described in the embodiments 1 and 2, and the description thereof will be omitted.

As illustrated in FIG. 9 to FIG. 11, the semiconductor device 1C according to the embodiment 3 is a through hole-type package semiconductor device, and a shape of the heat radiation plate 8 in the embodiment 3 is different from that in the embodiment 1. Specifically, the heat radiation plate 7 and the heat radiation plate 8 protrude from the same height position of the sealing resin 2, and do not have a level difference.

As illustrated in FIG. 11, the upper surface (surface in the +Z direction) of the heatsink 9 is provided with an insulation ceramic plate 13, and an upper surface (surface in the +Z direction) of the insulation ceramic plate 13 is provided with a copper pattern 14. When the plurality of semiconductor devices 1C are connected to the upper surface (+Z direction) of the heatsink 9 via the copper pattern 14 and the insulation ceramic plate 13, the screw 12 is inserted into each the screw hole 7a of the heat radiation plate 7 and the screw hole 8a of the heat radiation plate 8. The space 11a intervenes between the screw 12 and the heatsink 9 to insulate the screw 12 from the heatsink 9.

In the embodiment 3, the heat radiation plate 7 included in the semiconductor device 1C on the left side (−X direction) and the heat radiation plate 8 included in the semiconductor device 1C on the right side (X direction) are not directly connected to each other, however, they are electrically connected to each other via the copper pattern 14. Accordingly, inductance of the drain terminal 4 and the source terminal 5 can be reduced, and the drain terminal 4 and the source terminal 5 can be connected with low impedance.

An arrangement position of each terminal of the embodiment 2 can also be adopted to the embodiment 3.

As described above, in the semiconductor device 1C according to the embodiment 3, the heat radiation plate 7 and the heat radiation plate 8 protrude from the same height position of the sealing resin 2, and do not have a level difference. The semiconductor device 1C is the through hole-type package semiconductor device, the upper surface (surface in the +Z direction) of the heatsink 9 is provided with the insulation ceramic plate 13, and the upper surface (surface in the +Z direction) of the insulation ceramic plate 13 is provided with the copper pattern 14, thus the heat radiation plate 7 included in the semiconductor device 1C on the left side (−X direction) and the heat radiation plate 8 included in the semiconductor device 1C on the right side (X direction) can be electrically connected to each other via the copper pattern 14 by screwing.

Accordingly, occurrence of surge voltage can be suppressed, and a heat radiation property can be improved in the semiconductor device 1C in the manner similar to the case of the embodiment 1. Furthermore, the heat radiation plate 7 and the heat radiation plate 8 are not directly connected to each other, thus the spacer 11b is unnecessary, and a type of the spacer can be reduced compared with the case of the embodiment 1.

### Embodiment 4

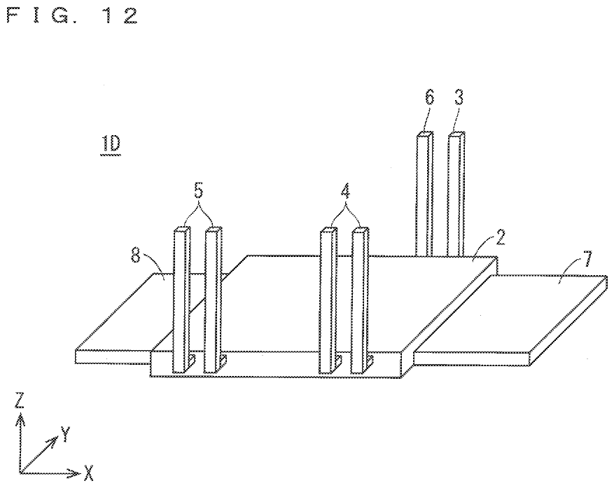

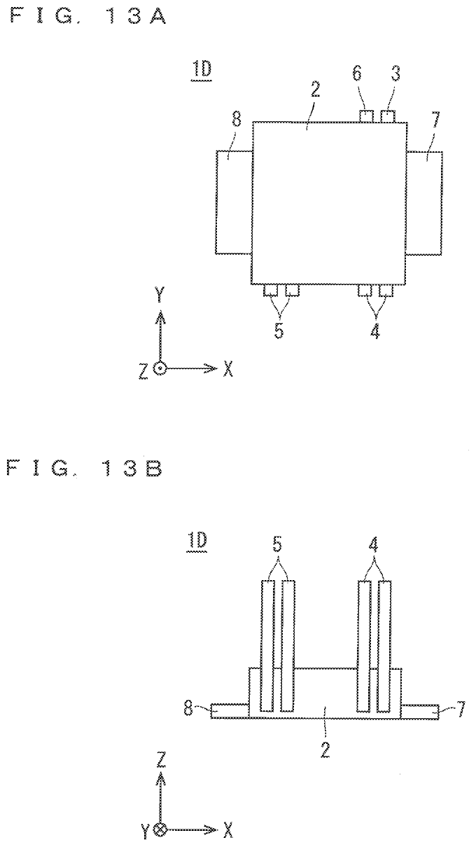

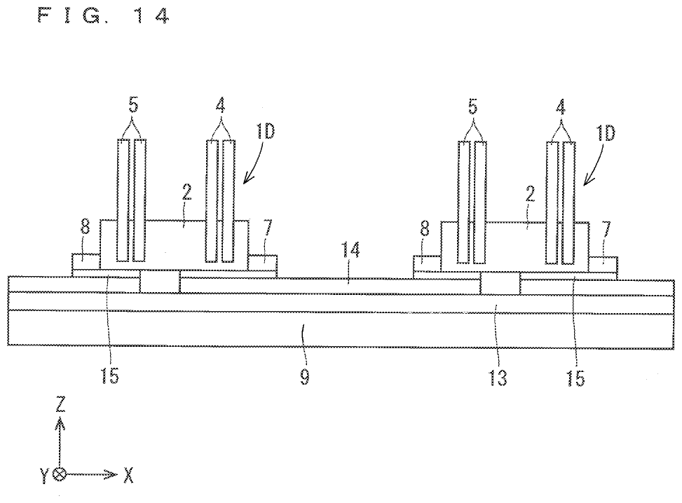

A semiconductor device 1D according to an embodiment 4 is described next. FIG. 12 is a perspective view of the semiconductor device 1D according to the embodiment 4. FIG. 13A is a top view of the semiconductor device 1D, and FIG. 13B is a front view of the semiconductor device 1D. FIG. 14 is a front view illustrating a state where the plurality of semiconductor devices 1D according to the embodiment 4 are connected to each other and fixed to a heatsink 9. In the description in the embodiment 4, the same reference numerals are assigned to the same constituent elements as those described in the embodiments 1 to 3, and the description thereof will be omitted.

As illustrated in FIG. 12 to FIG. 14, the semiconductor device 1D according to the embodiment 4 is a through hole-type package semiconductor device, and the embodiment 4 is different from the embodiment 3 in that the screw holes 7a and 8a are not provided in the heat radiation plate 7 and the heat radiation plate 8, respectively. Thus, the heat radiation plate 7 and the heat radiation plate 8 are bonded to the copper pattern 14 via a solder 15.

An arrangement position of each terminal of the embodiment 2 can also be adopted to the embodiment 4.

As described above, in the semiconductor device 1D according to the embodiment 4, the screw holes 7a and 8a for fixing the heat radiation plate 7 and the heat radiation plate 8 are not provided therein, respectively. Accordingly, occurrence of surge voltage can be suppressed, and a heat radiation property can be improved in the semiconductor device 1D in the manner similar to the case of the embodiment 1. The screw 12 is not used at the time of fixing the heat radiation plate 7 and the heat radiation plate 8 to the heatsink 9 via the copper pattern 14, thus the spacers 11a and 11b are unnecessary.

### Embodiment 5

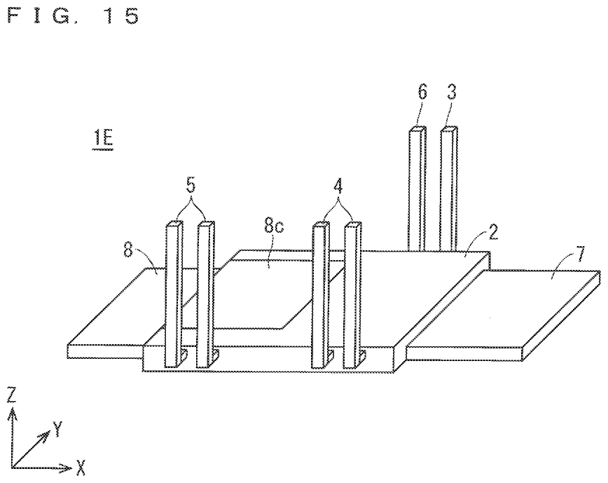

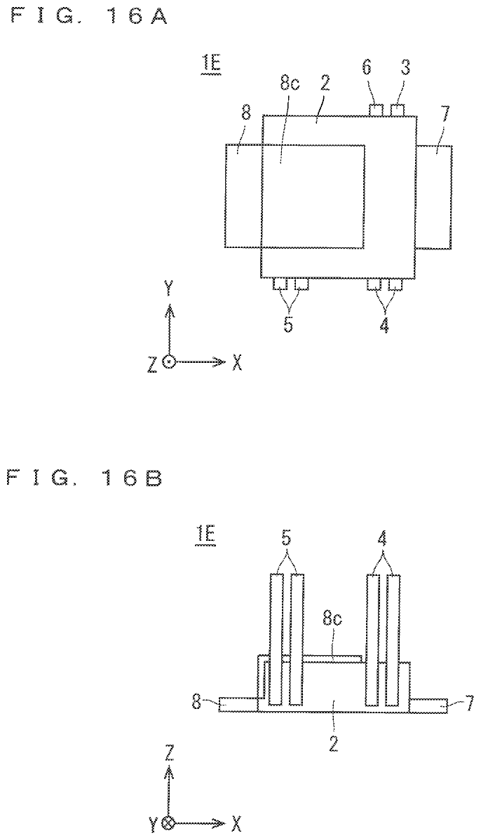

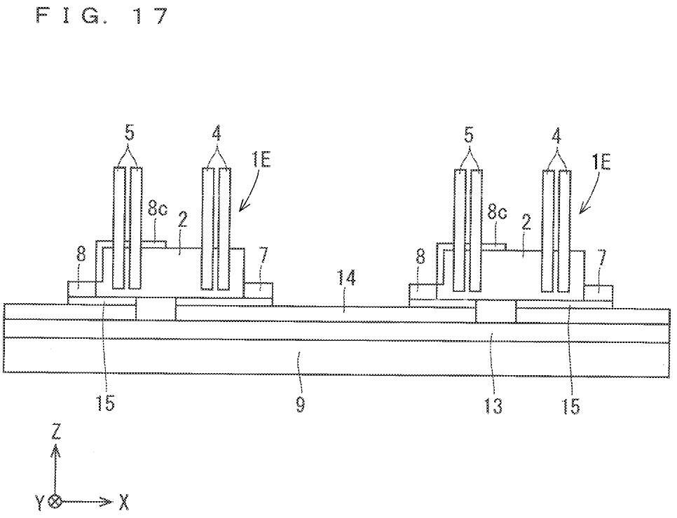

A semiconductor device 1E according to an embodiment 5 is described next. FIG. 15 is a perspective view of the semiconductor device 1E according to the embodiment 5. FIG. 16A is atop view of the semiconductor device 1E, and FIG. 16B is a front view of the semiconductor device 1E. FIG. 17 is a front view illustrating a state where the plurality of semiconductor devices 1E are connected to each other and fixed to a heatsink 9. In the description in the embodiment 5, the same reference numerals are assigned to the same constituent elements as those described in the embodiments 1 to 4, and the description thereof will be omitted.

As illustrated in FIG. 15 to FIG. 17, the semiconductor device 1E according to the embodiment 5 is a through hole-type package semiconductor device, and the embodiment 5 is different from the embodiment 4 in that a base end portion 8c of the heat radiation plate 8 extends to a side of an inner periphery of the sealing resin 2, and is exposed from the surface (surface in the Z direction) of the sealing resin 2 on a side opposite to the surface (surface in the −Z direction) thereof fixed to the heatsink 9. That is to say, a part of the heat radiation plate 8 is exposed from the upper surface (surface in the Z direction) of the sealing resin 2. Accordingly, an exposure area of the heat radiation plate 8 is increased compared with the cases of the embodiments 1 to 4.

A structure of the heat radiation plate 8 of the embodiment 5 can also be adopted to the embodiments 1 to 3.

As described above, in the semiconductor device 1E according to embodiment 5, the base end portion 8c of the heat radiation plate 8 extends to the side of the inner periphery of the sealing resin 2, and is exposed from the surface (surface in the Z direction) of the sealing resin 2 on the side opposite to the surface (surface in the −Z direction) thereof fixed to the heatsink 9. Accordingly, occurrence of surge voltage can be suppressed, and a heat radiation property can be improved in the semiconductor device 1E in the manner similar to the case of the embodiment 1. The exposure area of the heat radiation plate 8 is increased compared with the cases of the embodiments 1 to 4, thus the heat radiation property of the semiconductor device 1E can be further improved.

Each embodiment can be arbitrarily combined, or each embodiment can be appropriately varied or omitted.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device which can be connected to a heatsink, comprising:
a semiconductor element including a first electrode and a second electrode;
sealing resin formed into a rectangular shape in a top view to seal the semiconductor element;
a first heat radiation plate electrically connected to the first electrode, and protruding from a first side of the sealing resin in a top view;
a second heat radiation plate electrically connected to the second electrode, and protruding from a second side facing the first side of the sealing resin in a top view;
a first terminal electrically connected to the first electrode, and protruding from a third side intersecting with the first side of the sealing resin in a top view; and
a second terminal electrically connected to the second electrode, and protruding from the third side of the sealing resin in a top view, wherein
the first heat radiation plate and the second heat radiation plate can be fixed to the heatsink.

2. A semiconductor device which can be connected to a heatsink, comprising:
a semiconductor element including a first electrode and a second electrode;
sealing resin formed into a rectangular shape in a top view to seal the semiconductor element;
a first heat radiation plate electrically connected to the first electrode, and protruding from a first side of the sealing resin in a top view;
a second heat radiation plate electrically connected to the second electrode, and protruding from a second side facing the first side of the sealing resin in a top view;
a first terminal electrically connected to the first electrode, and protruding from the first side of the sealing resin in a top view; and
a second terminal electrically connected to the second electrode, and protruding from the second side of the sealing resin in a top view, wherein
the first heat radiation plate and the second heat radiation plate can be fixed to the heatsink.

3. The semiconductor device according to claim 1, wherein
one of the first heat radiation plate and the second heat radiation plate has a level difference, and
a height position of a lower surface of a tip end portion of one of the first and second heat radiation plates and a height position of an upper surface of a base end portion of the other one of the first and second heat radiation plates are identical with each other.

4. The semiconductor device according to claim 2, wherein
one of the first heat radiation plate and the second heat radiation plate has a level difference, and
a height position of a lower surface of a tip end portion of one of the first and second heat radiation plates and a height position of an upper surface of a base end portion of the other one of the first and second heat radiation plates are identical with each other.

5. The semiconductor device according to claim 1, wherein
the first heat radiation plate and the second heat radiation plate protrude from an identical height position of the sealing resin, and do not have a level difference.

6. The semiconductor device according to claim 2, wherein
the first heat radiation plate and the second heat radiation plate protrude from an identical height position of the sealing resin, and do not have a level difference.

7. The semiconductor device according to claim 1, wherein
a screw hole for fixing the first heat radiation plate and the second heat radiation plate to the heatsink is provided in the first heat radiation plate and the second heat radiation plate.

8. The semiconductor device according to claim 2, wherein
a screw hole for fixing the first heat radiation plate and the second heat radiation plate to the heatsink is provided in the first heat radiation plate and the second heat radiation plate.

9. The semiconductor device according to claim 5, wherein
a screw hole for fixing the first heat radiation plate and the second heat radiation plate to the heatsink is not provided in the first heat radiation plate and the second heat radiation plate.

10. The semiconductor device according to claim 6, wherein
a screw hole for fixing the first heat radiation plate and the second heat radiation plate to the heatsink is not provided in the first heat radiation plate and the second heat radiation plate.

11. The semiconductor device according to claim 1, wherein
a base end portion of the second heat radiation plate extends to a side of an inner periphery of the sealing resin, and is exposed from a surface of the sealing resin on a side opposite to a surface fixed to the heatsink.

12. The semiconductor device according to claim 2, wherein
a base end portion of the second heat radiation plate extends to a side of an inner periphery of the sealing resin, and is exposed from a surface of the sealing resin on a side opposite to a surface fixed to the heatsink.

13. The semiconductor device according to claim 1, wherein
the semiconductor element is a transistor or a diode.

14. The semiconductor device according to claim 2, wherein
the semiconductor element is a transistor or a diode.
